(19) United States
(12) Patent Application Publication
(10) Pub. No.: US 2009/0117742 A1
(43) Pub. Date: May 7, 2009

(54) METHOD FOR FABRICATING FINE PATTERN IN SEMICONDUCTOR DEVICE

(75) Inventor: Jin-Ki JUNG, Ichon-shi (KR)

Correspondence Address: TOWNSEND AND TOWNSEND AND CREW, LLP, TWO EMBARCADERO CENTER, EIGHTH FLOOR, SAN FRANCISCO, CA, 94111-3834, US

(73) Assignee: Hynix Semiconductor Inc., Ichon-shi (KR)

(21) Appl. No.: 12/164,066

(22) Filed: Jun. 29, 2008

(30) Foreign Application Priority Data
Nov. 2, 2007 (KR) 10-2007-0111761

(51) Int. Cl. H01L 21/308

(52) U.S. Cl. 438/694; 257/E21.231

(57) ABSTRACT

A method for fabricating a pattern in a semiconductor device includes a single polysilicon hard mask by appropriately selecting spacer material in an SPT, thereby decreasing the number of fabrication processes. Furthermore, since the spacers are easily removed, it is possible to prevent the formation of a step between patterns of a cell region and a peripheral region.

### CROSS-REFERENCE TO RELATED APPLICATIONS

The present invention claims priority of Korean patent application number 2007-0111761, filed on Nov. 2, 2007, which is incorporated by reference in its entirety.

### BACKGROUND OF THE INVENTION

The present invention relates a semiconductor device, and more particularly, to a method for fabricating a fine pattern in a semiconductor device using a polysilicon hard mask.

A gate pattern of a dynamic random access memory (DRAM) or a metal interconnection of a flash memory is formed by etching an insulation layer. For example, the formation of a gate pattern of a DRAM requires an etching of a gate hard mask which is generally formed of nitride. The formation of a metal interconnection of a flash memory requires an etching of a dual layer having a nitride layer and an oxide layer to form a trench for a metal interconnection. Generally, a polysilicon hard mask which can secure an etch selectivity relative to the nitride layer is used to etch the nitride layer.

As the integration density of a semiconductor device increases, sub-micron patterns are required. However, due to the resolution limitation of an existing exposure apparatus, it is substantially impossible to form sub-40 nm patterns. Recently, a spacer patterning technology (SPT) was proposed which etches a lower layer using a spacer as a hard mask. The SPT has been applied to a cell region where patterns should be formed with a small width below the exposure limitation. A typical SPT will be described below with reference to FIGS. 1A to 1F. In particular, a method for forming a metal interconnection of a flash memory will be exemplified.

FIGS. 1A to 1F illustrate a method for forming a metal interconnection of a flash memory using a typical SPT.

Referring to FIG. 1A, a substrate (not shown) has a cell region, where a pattern having a small width is to be formed, and a peripheral region, where a pattern having a relatively large width is to be formed. An insulation layer 11 is formed over the substrate (not shown). A trench for a metal interconnection will be formed in the insulation layer 11. That is, the insulation layer 11 is an etch target layer. The insulation layer 11 may have a stacked structure of a nitride layer 11A and an oxide layer 11B.

A polysilicon hard mask 12 is formed over the insulation layer 11.

A nitride hard mask 13 is formed over the polysilicon hard mask 12. That is, a dual-layer structure where the nitride layer is stacked on the polysilicon layer is used as the hard mask. This is done for securing an etch selectivity because a polysilicon spacer is used in a subsequent spacer forming process.

A sacrificial pattern 14 is formed in the cell region over the nitride hard mask 13, and polysilicon spacers 15 are formed on sidewalls of the sacrificial pattern 14. The sacrificial pattern 14 may be formed of oxide.

Referring to FIG. 1B, the sacrificial pattern 14 is removed so that the polysilicon spacers 15 remain in the cell region over the nitride hard mask 13. In a subsequent process, lower layers formed in the cell region are etched using the polysilicon spacers 15. Thus, patterns with small widths below an exposure limitation can be formed in the cell region.

Since the formation of patterns with small widths below the exposure limitation is not required in the peripheral region, the SPT need not be applied. Referring to FIG. 1C, photoresist patterns 16 are formed in the peripheral region over the nitride hard mask 13.

Referring to FIG. 1D, first and second nitride hard mask patterns 13A and 13B are formed by etching the nitride hard mask 13 using the polysilicon spacers 15 of the cell region and the photoresist patterns 16 of the peripheral region as an etch barrier. The photoresist patterns 16 may be removed by a photoresist strip process. However, since the polysilicon spacers 15 are not easily removed, most of the polysilicon spacers 15 remain even after etching the nitride hard mask 13. Therefore, in a subsequent process of etching the polysilicon hard mask 12, the etch barrier of the cell region (the polysilicon spacers 15 and the first nitride hard mask pattern 13A) becomes different from the etch barrier of the peripheral region (the second nitride hard mask pattern 13B).

Referring to FIG. 1E, polysilicon hard mask patterns 12 are formed by etching the polysilicon hard mask 12 using the polysilicon spacer 15 and the first nitride hard mask pattern 13A of the cell region and the second nitride hard mask pattern 13B of the peripheral region as an etch barrier. In this case, due to the presence of the polysilicon spacers 15, the first nitride hard mask patterns 13A remain in the cell region and thus the polysilicon hard mask 12 is completely protected. However, the second nitride hard mask patterns 13B of the peripheral region are mostly removed and thus the polysilicon hard mask 12 may be damaged. In other words, due to the difference in the etch barriers remaining on the polysilicon hard mask 12 in the process of FIG. 1D, a step is formed between the first polysilicon hard mask pattern 12A of the cell region and the second polysilicon hard mask pattern 12B of the peripheral region in the process of FIG. 1E.

Referring to FIG. 1F, first and second insulation patterns 11A and 11B that define trenches for metal interconnection are formed by etching the insulation layer 11 using the first nitride hard mask pattern 13A and the first polysilicon hard mask pattern 12A of the cell region, and the second polysilicon hard mask pattern 12B of the peripheral region as an etch barrier. As described above with reference to FIG. 1E, since the etch barriers remaining on the insulation layer 11 are different in the cell region and the peripheral region, the step is formed between the first insulation pattern 11A of the cell region and the second insulation pattern 11B of the peripheral region.

Although not shown, a metal interconnection is formed to fill the trench, that is, the space defined between the first and second insulation patterns 11A and 11B.

The typical SPT has the following limitations.

When the polysilicon hard mask is used, the polysilicon spacers are used for applying the SPT in the cell region. Therefore, the hard mask, such as the nitride hard mask, which has a different etch selectivity relative to polysilicon, is necessarily formed over the polysilicon hard mask.

However, the use of such a dual-layered hard mask increases the number of the fabrication processes because the hard mask forming process and the etching process are performed again.

Furthermore, the polysilicon spacers are not easily removed. In the subsequent processes, the step is formed between the patterns of the cell region and the peripheral region.

### SUMMARY OF THE INVENTION

Embodiments of the present invention are directed to providing a method for fabricating a fine pattern in a semiconductor device, which uses a single polysilicon hard mask by appropriately selecting spacer material in an SPT, thereby decreasing the number of fabrication processes. Furthermore, since the spacers are easily removed, it is possible to prevent the formation of a step between patterns of a cell region and a peripheral region.

In accordance with an aspect of the present invention, a method for fabricating a pattern in a semiconductor device includes forming an etch target layer over a substrate having a first region, where a pattern having a small line width is to be formed, and a second region, where a pattern having a large line width is to be formed; forming a polysilicon hard mask over the etch target layer; forming a sacrificial pattern in the first region over the polysilicon hard mask; forming carbon-containing polymer spacers on sidewalls of the sacrificial pattern; removing the sacrificial pattern; forming a photoresist pattern in the second region over the polysilicon hard mask; etching the polysilicon hard mask using the carbon-containing polymer spacers and the photoresist pattern as an etch barrier; removing the carbon-containing polymer spacers and the photoresist pattern by a photoresist strip process; and etching the etch target layer using the etched polysilicon hard mask as an etch barrier.

In accordance with another aspect of the present invention, a method for fabricating a pattern in a semiconductor device includes forming an etch target layer over a substrate having a first region, where a pattern having a small line width is to be formed, and a second region, where a pattern having a large line width is to be formed; forming a polysilicon hard mask over the etch target layer, forming a sacrificial pattern in the first region over the polysilicon hard mask; forming nitride spacers on sidewalls of the sacrificial pattern; removing the sacrificial pattern; forming a photoresist pattern in the second region over the polysilicon hard mask; etching the polysilicon hard mask using the nitride spacers and the photoresist pattern as an etch barrier; removing the photoresist pattern; removing the nitride spacers; and etching the etch target layer using the etched polysilicon hard mask as an etch barrier.

### BRIEF DESCRIPTION OF THE DRAWINGS

FIGS. 1A to 1F illustrate a method for forming a metal interconnection of a flash memory using a typical SPT.

FIGS. 2A to 2G illustrate a method for fabricating a fine pattern in a semiconductor device using an SPT in accordance with an embodiment of the present invention.

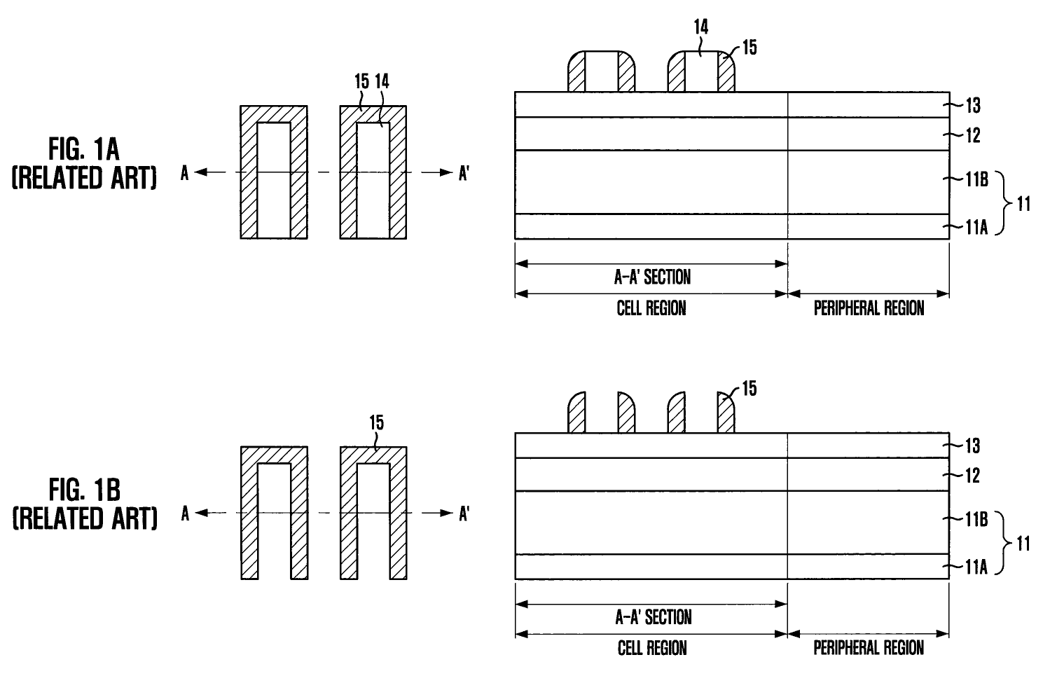

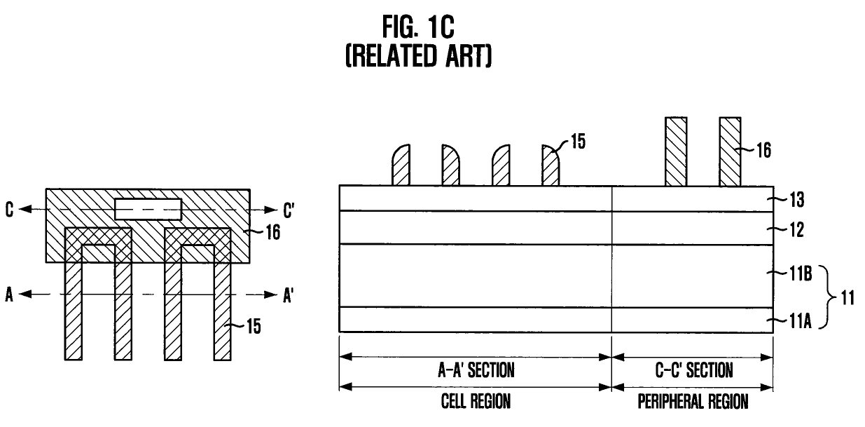

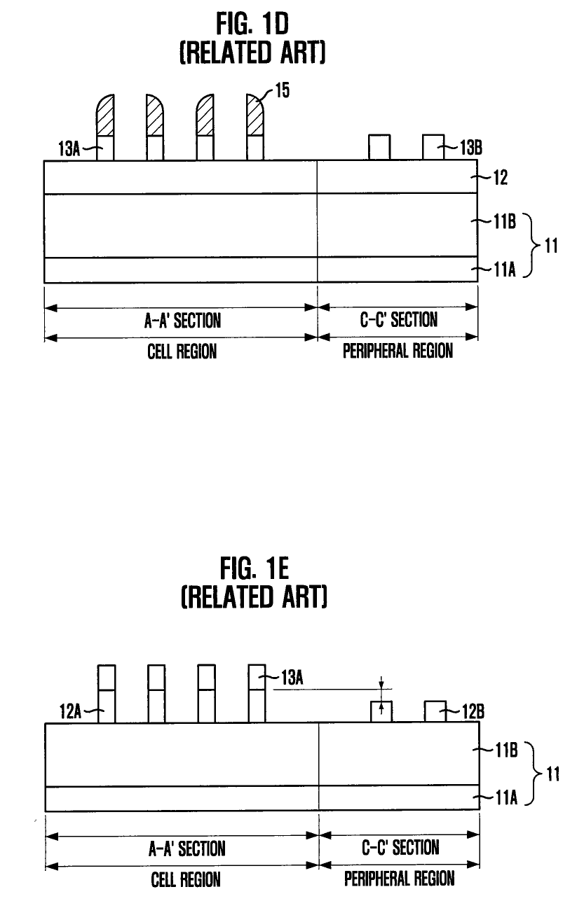

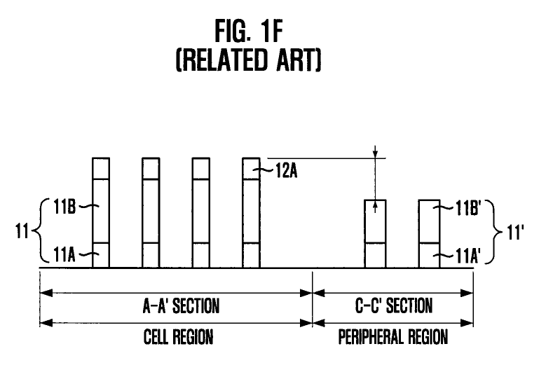

### DESCRIPTION OF SPECIFIC EMBODIMENTS

Embodiments of the present invention relate to a method for fabricating a semiconductor device, and more particularly, to a method for fabricating a fine pattern in a semiconductor device.

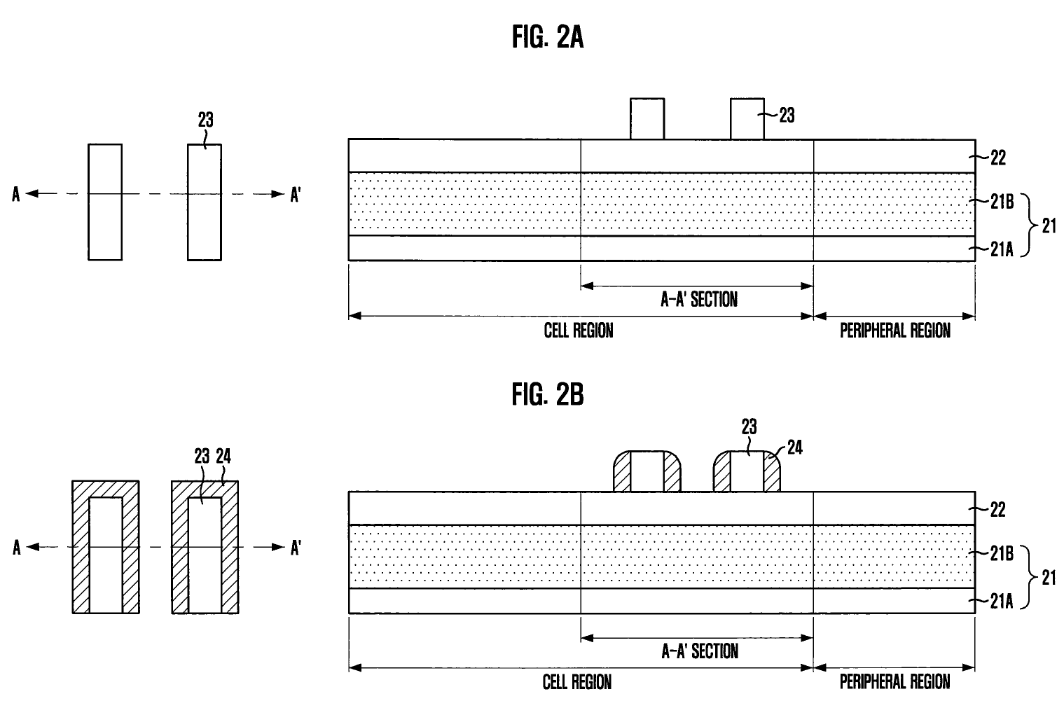

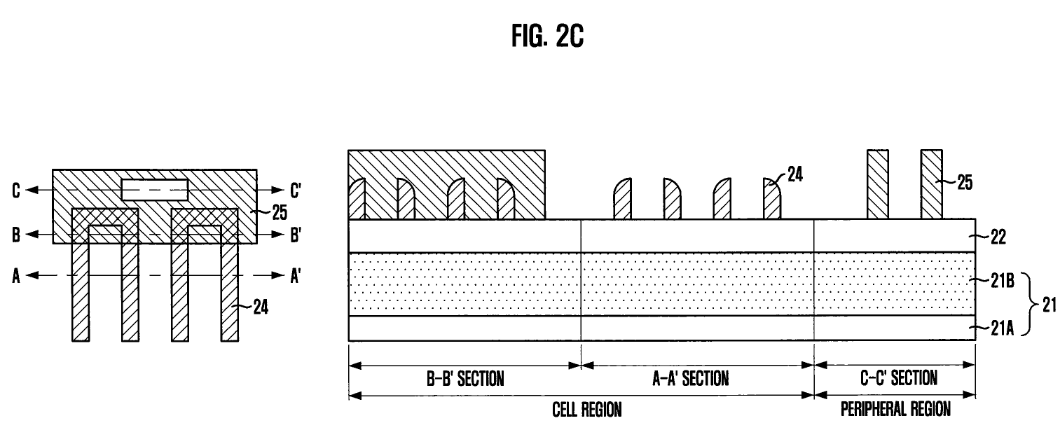

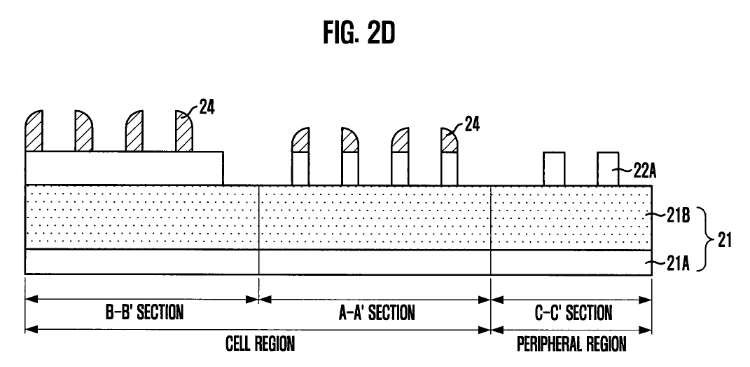

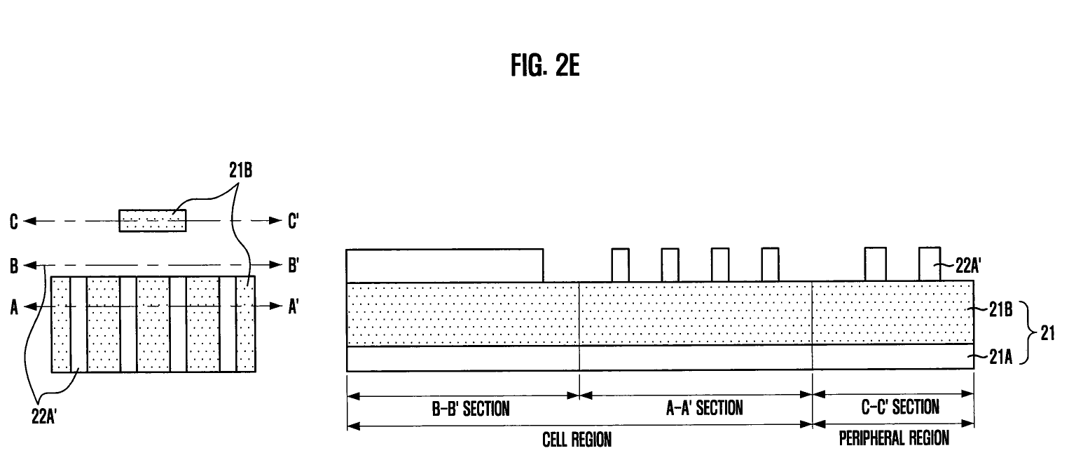

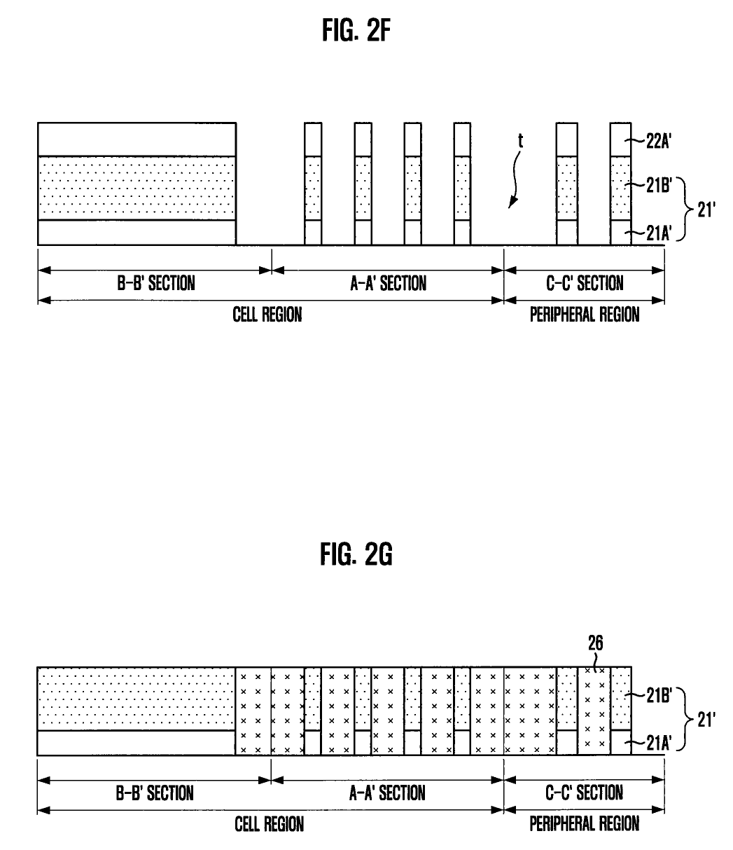

FIGS. 2A to 2G illustrate a method for fabricating a fine pattern in a semiconductor device using an SPT in accordance with an embodiment of the present invention. In particular, a method for fabricating a metal interconnection of a flash memory will be described as an example.

Referring to FIG. 2A, a substrate (not shown) has a cell region, where a pattern having a small width is to be formed, and a peripheral region, where a pattern having a relatively large width is to be formed. An insulation layer 21 is formed as an etch target layer over the substrate (not shown). A trench for a metal interconnection will be formed in the insulation layer 21. The insulation layer 21 may have a stacked structure of a nitride layer 21A and an oxide layer 21B.

A polysilicon hard mask 22 is formed over the insulation layer 21.

A sacrificial pattern 23 is formed over the polysilicon hard mask 22. The sacrificial patterns 23 are appropriately selected according to spacer materials, which will be described below with reference to FIG. 2B.

Referring to FIG. 2B, spacers 24 are formed on sidewalls of the sacrificial pattern 23. Since an etching of the insulation layer 21 will be performed using the single polysilicon hard mask 22, the spacers 24 are formed of material different from the typical polysilicon.

The spacers 24 may be formed of a carbon-containing polymer. In this case, the sacrificial pattern 23 may be formed of nitride. If the spacers 24 are formed of carbon-containing polymer, an etch selectivity relative to the polysilicon hard mask 22 can be ensured. Furthermore, the spacers 24 can be easily removed together with photoresist in a subsequent photoresist strip process. The formation of the carbon-containing polymer may be performed by a deposition process using at least one of CHₓF_{y} (e.g., trifluoromethane (CHF₃), difluoromethane (CH₂F₂), fluoromethane (CH₃F), etc.) plasma, CₓF_{y} (e.g., hexafluoroethane (C₂F₆), hexafluoro-1,3-Butadiene (C₄F₆), isoprene (C₅H₈), isobutylene (C₄H₈), C₃F₃, etc.) plasma, and CₓH_{y} (e.g., methane (CH₄), trideuterioethene (C₂H₄), etc.) plasma.

Alternatively, the spacers 24 may be formed of nitride. In this case, the sacrificial pattern 23 may be formed of oxide or amorphous carbon. If the spacers 24 are formed of nitride, an etch selectivity relative to the polysilicon hard mask 22 can be ensured. Furthermore, the spacers 24 can be easily removed by a phosphoric acid containing solution.

The sacrificial pattern 23 is removed. If the sacrificial pattern 23 is formed of nitride, it can be removed by a phosphoric acid containing solution. If the sacrificial pattern 23 is formed of oxide, it can be removed by a fluoric acid containing solution. If the sacrificial pattern 23 is formed of amorphous carbon, it can be removed by a strip process using O₂ plasma.

Referring to FIG. 2C, photoresist patterns 25 are formed in the peripheral region C-C′ and an edge portion B-B′ of the cell region over the polysilicon hard mask 22.

Referring to FIG. 2D, polysilicon hard mask patterns 22A are formed by etching the polysilicon hard mask 22 using the spacers 24 and the photoresist patterns 25 as an etch barrier.

The photoresist patterns 25 are removed by a photoresist strip process using O₂ plasma.

Referring to FIG. 2E, when the spacers 24 are formed of carbon-containing polymer, they are removed in the process of removing the photoresist patterns 25, so that the polysilicon hard mask patterns 22A′ remain on the insulation layer 21. On the other hand, as illustrated in FIG. 2E, when the spacers 24 are formed of nitride, the polysilicon hard mask patterns 22A′ remain on the insulation layer 21 by performing a separate removing process using a phosphoric acid containing solution.

Referring to FIG. 2F, the insulation layer 21 is etched using the polysilicon hard mask patterns 22A′ of the cell region and the peripheral region to form first and second insulation patterns 21′ defining a trench t for metal interconnection. Since the size of the etch barrier of the cell region is equal to the size of the etch barrier of the peripheral region, a step is not formed between the first and second insulation patterns 21′.

Referring to FIG. 2G, the trench t, that is, the space defined between the first and second insulation patterns 21′ is filled with a metal to form a metal interconnection 26.

When etching the lower layers using the polysilicon hard mask, the SPT is applied to the cell region and the carbon-containing polymer or a nitride layer is used as the spacers. Thus, hard masks other than the polysilicon hard mask are not required, thereby preventing the increase in the number of fabrication processes.

Furthermore, since the carbon-containing polymer or nitride layer used as the spacers is easily removed by the strip process or the phosphoric acid containing solution, the patterns can be formed in both the cell region and the peripheral region using the polysilicon hard mask, thereby preventing the formation of the step between the patterns.

By appropriately selecting the spacer materials in the SPT, the single polysilicon hard mask can be used, thereby decreasing the number of the fabrication process. Furthermore, since the spacers are easily removed, it is possible to prevent the formation of the step between the patterns of the cell region and the peripheral region.

While the present invention has been described with respect to the specific embodiments, it will be apparent to those skilled in the art that various changes and modifications may be made without departing from the spirit and scope of the invention as defined in the following claims.

Although the process of etching the nitride layer for forming the metal interconnection of the flash memory has been described above, the present invention is not limited to the above-described embodiment. The present invention can also be applied to technologies requiring the formation of fine patterns such as a gate pattern.

What is claimed is:

1. A method for fabricating a pattern in a semiconductor device, the method comprising:
forming an etch target layer over a substrate having a first region and a second region, wherein a pattern having a small line width is to be formed in the first region and a pattern having a large line width is to be formed in the second region;
forming a polysilicon hard mask over the etch target layer;
forming a sacrificial pattern in the first region over the polysilicon hard mask;
forming carbon-containing polymer spacers on sidewalls of the sacrificial pattern;
removing the sacrificial pattern;
forming a photoresist pattern in the second region over the polysilicon hard mask;
etching the polysilicon hard mask using the carbon-containing polymer spacers and the photoresist pattern as an etch barrier;
removing the carbon-containing polymer spacers and the photoresist pattern by a photoresist strip process; and
etching the etch target layer using the etched polysilicon hard mask as an etch barrier.

2. The method of claim 1, wherein the sacrificial pattern comprises nitride.

3. The method of claim 2, wherein removing the sacrificial pattern is performed using a phosphoric acid containing solution.

4. The method of claim 1, wherein forming the carbon-containing polymer spacers is performed by a deposition process using at least one of CHₓF_{y} plasma, CₓF_{y} plasma, and CₓH_{y} plasma.

5. The method of claim 1, wherein the photoresist strip process is performed using O₂ plasma.

6. The method of claim 1, wherein the etch target layer is formed of nitride.

7. The method of claim 6, wherein the etch target layer has a stacked structure of a nitride layer and an oxide layer.

8. The method of claim 1, wherein the first region is a cell region, and the second region is a peripheral region.

9. A method for fabricating a pattern in a semiconductor device, the method comprising:
forming an etch target layer over a substrate having a first region and a second region, wherein a pattern having a small line width is to be formed in the first region and a pattern having a large line width is to be formed in the second region;
forming a polysilicon hard mask over the etch target layer;
forming a sacrificial pattern in the first region over the polysilicon hard mask;
forming nitride spacers on sidewalls of the sacrificial pattern;
removing the sacrificial pattern;
forming a photoresist pattern in the second region over the polysilicon hard mask;
etching the polysilicon hard mask using the nitride spacers and the photoresist pattern as an etch barrier;
removing the photoresist pattern;
removing the nitride spacers; and
etching the etch target layer using the etched polysilicon hard mask as an etch barrier.

10. The method of claim 9, wherein the sacrificial pattern comprises oxide.

11. The method of claim 9, wherein the sacrificial pattern comprises amorphous carbon.

12. The method of claim 10, wherein removing the sacrificial pattern is performed using a fluoric acid containing solution.

13. The method of claim 11, wherein forming the sacrificial pattern is performed by a strip process using O₂ plasma.

14. The method of claim 9, wherein removing the photoresist pattern is performed by a photoresist strip process.

15. The method of claim 9, wherein removing the nitride spacers is performed using a phosphoric acid containing solution.

16. The method of claim 9, wherein the etch target layer comprises nitride.

17. The method of claim 16, wherein the etch target layer has a stacked structure of a nitride layer and an oxide layer.

18. The method of claim 9, wherein the first region is a cell region, and the second region is a peripheral region.
